(19) United States
(12) Patent Application Publication
(10) Pub. No.: US 2018/0259578 A1
(43) Pub. Date: Sep. 13, 2018

(54) METHOD AND APPARATUS FOR DYNAMIC CONTROLLER BIST

(71) Applicant: QUALCOMM Incorporated, San Diego, CA (US)

(72) Inventor: Praveen Raghuraman, Chennai (IN)

(21) Appl. No.: 15/862,554

(22) Filed: Jan. 4, 2018

Related U.S. Application Data
(60) Provisional application No. 62/470,825, filed on Mar. 13, 2017.

(51) Int. Cl. G01R 31/317; G01R 31/3187; G01R 31/3185

(52) U.S. Cl. CPC G01R 31/31724; G01R 31/3187; G06F 2201/83; G01R 31/318563; G01R 31/31707

(57) ABSTRACT

A BIST circuit is provided with modes of operation in which the BIST procedure for a circuit-under-test occurs at a system clock rate for the circuit-under-test that is greater than a test clock rate for the BIST circuit.

### REFERENCE TO RELATED APPLICATIONS

This application claims the benefit of U.S. Patent Application No. 62/470,825 filed Mar. 13, 2017, which is incorporated herein by reference in its entirety.

### TECHNICAL FIELD

This application relates to testing of integrated circuits, and more particularly to an integrated circuit with a dynamically controlled built-in-self-test (BIST) circuit.

### BACKGROUND

A modem system-on-a-chip will typically include an assortment of processor cores, subsystems, and scores of embedded memories. The complexity of testing so many inter-connected subsystems would be overwhelming without the use of built-in self-test (BIST) circuits. For example, the embedded memories may be associated with an embedded memory BIST circuit, the WiFi interface with its own BIST circuit, and so on. The various BIST circuits are accessed through corresponding test access ports (TAPs). Each BIST circuit includes a BIST controller that controls the generation of an input test vector that is shifted into the corresponding subsystem responsive to a BIST test clock (TCK). The test clock typically cycles at a relatively slow rate such as ¼ the frequency for a reference clock signal that is used to generate a subsystem clock for clocking the subsystem during normal operation. If the BIST circuit indicates a failure, the integrated circuit must then be subjected to testing in an automated test equipment that adds latency and cost to the manufacturing process.

Accordingly, there is a need in the art for improved BIST circuits offering increased testing flexibility.

### SUMMARY

A BIST operation results in either a passing result or a failing result for a circuit-under-test being tested by a BIST circuit. But a failing result may also be the result of a failure of the BIST circuit itself as opposed to a failure of the circuit-under-test. To provide increased testing flexibility so as to distinguish between a BIST circuit failure or a failure of the circuit-under-test, a BIST circuit is provided including a BIST controller having a plurality of dynamically controlled modes of operation. The BIST circuit is included within an integrated circuit that also includes the circuit-under-test. The modes of operation are selected for by external signals such as general-purpose-input-output (GPIO) signals. The modes of operation provide the BIST circuit with improved speed as well as greater diagnostic capability.

For example, in a fast-clocked mode of operation, the BIST circuit tests a circuit-under-test (for example, an embedded memory circuit) by shifting a test vector (or vectors) into the circuit-under-test according to cycles of a system reference clock signal such as a crystal oscillator reference clock signal. In contrast, the BIST circuit tests the circuit-under-test in a slow-clocked mode of operation by shifting in the appropriate test vector according to cycles of a BIST test clock signal. The BIST test clock signal is slower than the system clock signal such that a failing result for the slow-clocked mode of operation in conjunction with a successful result for the fast-clocked mode of operation points to a failure in the BIST circuit itself as opposed to a failure of the circuit-under-test. In contrast, a failing result for both the fast-clocked and slow-clocked modes of operation indicates a failure in the circuit-under-test. The fast-clocked mode of operation is also denoted herein as a first mode of operation. Similarly, the slow-clocked mode of operation is also denoted herein as a second mode of operation.

Depending upon the isolation of the fault in either the circuit-under-test or the BIST circuit, a test circuit or user controlling the external signals may then select for additional modes of operation to shift out the test results. For example, the BIST circuit shifts out the failure information for a fault in the circuit-under-test at the system clock rate in a third mode of operation. Conversely, the BIST circuit shifts out the failure information for a fault in the BIST circuit at the test clock rate in a fourth mode of operation. In this fashion, a user may quickly diagnose the failure in the field instead of the more conventional practice of shipping the faulty chip to the chip manufacturer's facility for automated test equipment (ATE) testing.

These and other advantageous features may be better appreciated through the following detailed description.

### BRIEF DESCRIPTION OF THE DRAWINGS

FIG. 1 is a diagram of an example dynamic BIST circuit in accordance with an aspect of the disclosure.

FIG. 2 is a flowchart for some example modes of operation for the dynamic BIST circuit of FIG. 1.

FIG. 3 is a flowchart for an example method of operation for a dynamic BIST circuit in accordance with an aspect of the disclosure.

Aspects of the present disclosure and their advantages are best understood by referring to the detailed description that follows. It should be appreciated that like reference numerals are used to identify like elements illustrated in one or more of the figures.

### DETAILED DESCRIPTION

To provide increased testing flexibility, a BIST circuit for an integrated circuit having a plurality of dynamically controlled modes is disclosed. For example, in a first mode of operation, the BIST circuit tests an embedded circuit-under-test in the integrated circuit by shifting a test vector into the circuit-under-test at a reference or system clock rate. The integrated circuit may include a clock source such as a crystal oscillator to produce the system clock signal. Alternatively, the integrated circuit may receive the system clock signal from an external source. The system clock signal is also denoted herein as a reference clock signal. Regardless of how the system clock signal is produced, its frequency is greater than the frequency for a BIST test clock received by the integrated circuit through a test access port (TAP). The BIST test clock is used by the BIST circuit in a second mode of operation to shift in the test vector (or test vectors). Because of the frequency difference between these two modes of operation, the first mode of operation may also be denoted as a fast-clocked mode of operation whereas the second mode of operation may also be denoted as a slow-clocked mode of operation.

The fast and slow clocked modes of operation allow a user to distinguish between a failure of the circuit-under-test and a failure of the BIST circuit itself. In particular, a failing result for both the fast-clocked and the slow-clocked modes of operation indicates that the failure lies with the circuit-under-test. Conversely, a failure of the BIST circuit itself is indicated if the failing result lies only with the fast-clocked mode of operation. The clock frequency selection for the first and second modes of operation is also applied to the shifting out of failure information resulting from the BIST circuit. There is thus a third mode of operation in which the failure information (which may also be designated as an output vector) for a fault in the circuit-under-test is shifted out of the BIST controller for the BIST circuit responsive to cycles of the system clock signal. Similarly, there is a fourth mode of operation in which the failure information for a fault in the BIST circuit is shifted out of the BIST controller responsive to cycles of the test clock signal. In this fashion, a user at a customer's facility may quickly diagnose the type of failure for the integrated circuit without the conventional and time-consuming need to ship the integrated circuit back to the manufacturer's facility for ATE testing. An example BIST circuit will now be discussed.

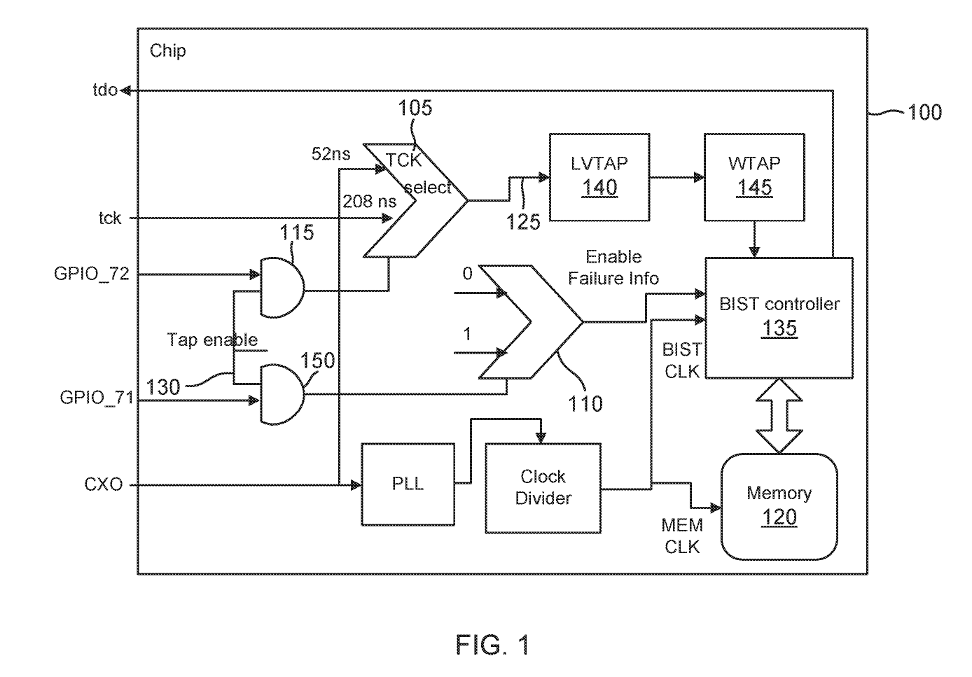

The following example BIST circuit is directed to the testing of an embedded memory. But it will be appreciated that the dynamic BIST modes disclosed herein may be advantageously applied to the testing of any suitable circuit-under-test. Turning now to the drawings, FIG. 1 illustrates an example BIST circuit for the dynamic testing of an embedded memory 120 within a die or integrated circuit 100. A user controls the modes of operation for the BIST circuit by controlling the binary state for one or more external signals applied to integrated circuit 100. With regard to these external signals, it is conventional for an integrated circuit to include a plurality of general-purpose-input-output (GPIO) pins or terminals. Depending upon a user's needs, a GPIO pin may be programmed to receive whatever digital signal that is required for a particular application. Integrated circuit 100 thus receives the external signals as GPIO signals such as a first GPIO signal (GPIO_72) and a second GPIO signal (GPIO_71). But it will be appreciated that other types of pins or terminals may be utilized in alternative implementations for receiving the external signals that control the selection of the modes of operation for the BIST circuit.

During a normal (non-test) mode of operation, memory 120 is clocked by a memory clock signal (MEM CLK). To form the memory clock signal, a system clock signal (cxo) such as a crystal oscillator signal is received by a phase-locked loop (PLL) to form a PLL clock that is divided in a clock divider. The memory clock signal is also used as a BIST clock (BIST CLK) to clock a BIST controller 135 in the BIST circuit. As discussed herein, the BIST circuit is modified so that input test vectors may be shifted into memory 120 at the memory clock signal rate in the first mode of operation for the BIST circuit as compared to the conventional use of a BIST test clock signal (TCK). In a second mode of operation for the BIST circuit, the input vectors are shifted into memory 120 responsive to cycles of the BIST test clock signal. The following discussion will be directed to an implementation in which there are four modes of operation for the BIST circuit. However, it will be appreciated that alternative implementations may have fewer (or greater) than four modes of operation.

It is conventional for a BIST circuit to include a BIST controller as well as a test pattern generator. The test pattern generator generates the test vector that is shifted into the circuit-under-test. In addition, a BIST circuit will also include a comparator for comparing the output vector resulting from the circuit-under-test with the expected result from normal operation. The BIST controller controls the operation of the test pattern generator and the comparator. In integrated circuit 100, BIST controller 135 is integrated with these additional conventional components. Although BIST controller 135 is clocked by a BIST clock that cycles at the memory clock rate, BIST controller 135 functions to shift the test vector from the associated test pattern generator at a clock rate received from a TAP. With regards to a TAP, integrated circuit 100 is a system-on-a-chip (SoC) such that it includes a variety of sub-systems (not illustrated) in addition to memory 120. Integrated circuit thus includes a global TAP 140 (LVTAP) and a local memory TAP 145 (WTAP). The BIST circuit includes a clock selection circuit such as formed by an AND gate 115 and a multiplexer 105 for changing the clock frequency of a TAP clock 125 coupled through TAPs 140 and 145 to BIST controller 135 to effect the first and second modes of operation.

It is arbitrary as to which binary state for the GPIO_72 and GPIO_71 signals selects for which mode of operation for the BIST circuit. The following binary states are thus merely exemplary and may be varied in alternative implementations. To select for the first mode of operation, both the GPIO_72 and GPIO_71 signals equal binary zero. AND gate 115 also receives a TAP enable signal that is asserted when the dynamic modes of operation are enabled. Thus an output of AND gate 115 will be asserted when both the GPIO_72 signal and the tap enable signals are asserted. Note that as used herein, a signal is deemed to be asserted when it is true regardless of whether such a binary true state is represented by a power supply voltage or ground. Multiplexer 105 responds to the assertion of the output signal from AND gate 115 by selecting for the system clock signal cxo to produce TAP clock signal 125. In one implementation, multiplexer 105 and AND gate 115 may be deemed for form a means for driving the BIST controller into a first mode of operation in which the BIST controller shifts a test vector into the circuit-under-test responsive to the reference clock signal and for driving the BIST controller into a second mode of operation in which the BIST controller shifts a test vector into the circuit-under-test responsive to a BIST clock signal, wherein a frequency for the reference clock signal is faster than a frequency for the BIST clock signal. Multiplexer 105 also receives the test clock signal (tck). Should the GPIO_72 signal be a binary zero, multiplexer 105 will thus select for the test clock signal to form TAP clock signal 125 in the second mode of operation.

If the system clock signal has a 52 nanosecond (ns) period corresponding to a frequency of approximately 19 MHz, then the input vector shifts in a bit in each 52 ns period of TAP clock 125 in the first mode of operation. In an alternative implementation, a double rate shifting may be employed such that two bits would be shifted in for each clock period. As discussed previously, the test clock signal is significantly slower than the system clock signal (e.g., ¼ the rate). Should the test clock have a period of 208 ns, then the input vector shifts in a bit at a time in each 208 ns period in the second mode of operation.

The first and second modes of operation may be modified to also output the test output vector (tdo) resulting from the testing of memory 120 through a selection by a multiplexer 110. The test output vector is also denoted herein as failure information. To control the additional modes of operation, multiplexer 110 selects between a binary zero or a binary one value for an enable failure information (enable failure info) signal. BIST controller 135 is modified to shift out the test output vector tdo responsive to the TAP clock rate responsive to an assertion of the enable failure information signal. For example, the first mode of operation becomes a third mode of operation in which the input vector is shifted into memory 120 at the system clock rate and the resulting test output vector is also shifted out from integrated circuit 100 at the system clock rate. Similarly, the second mode of operation becomes a fourth mode of operation in which the input vector is shifted into memory 120 at the test clock rate and the resulting test output vector is also shifted out from integrated circuit 100 at the test clock rate.

An AND gate 150 that processes the GPIO_71 signal and the TAP enable signal controls the selection by multiplexer 110 and thus controls whether the first and second modes of operation are shifted into the third and fourth mode of operation (respectively). The first mode of operation thus is selected for by the GPIO_72 signal and the GPIO_71 signal both being false (assuming that the TAP enable signal is also asserted). But this first mode of operation becomes the third mode of operation if the GPIO_71 signal is instead true. Similarly, the second mode of operation results from the GPIO_72 signal being true while the GPIO_71 signal is false (assuming again that the TAP enable signal is asserted). But the second mode of operation becomes the fourth mode of operation is the GPIO_71 signal is instead true.

The resulting dynamic control of the BIST circuit is quite advantageous with regard to obviating the prior art need of using specialized automatic test equipment to determine the failure. For example, suppose that the testing of memory 120 in the first mode of operation indicates a failure. The test may then be repeated using the second mode of operation. Should the second mode of operation result in no faults, the fault is actually within the BIST circuit itself as opposed to memory 120. Conversely, should both the first and second modes of operation indicate a failure, a fault within memory 120 may be presumed. The failure may then be examined in more detail by operation in the third or fourth modes of operation in that the output vector may be shifted out and analyzed in the field as compared to the conventional use of automated test equipment.

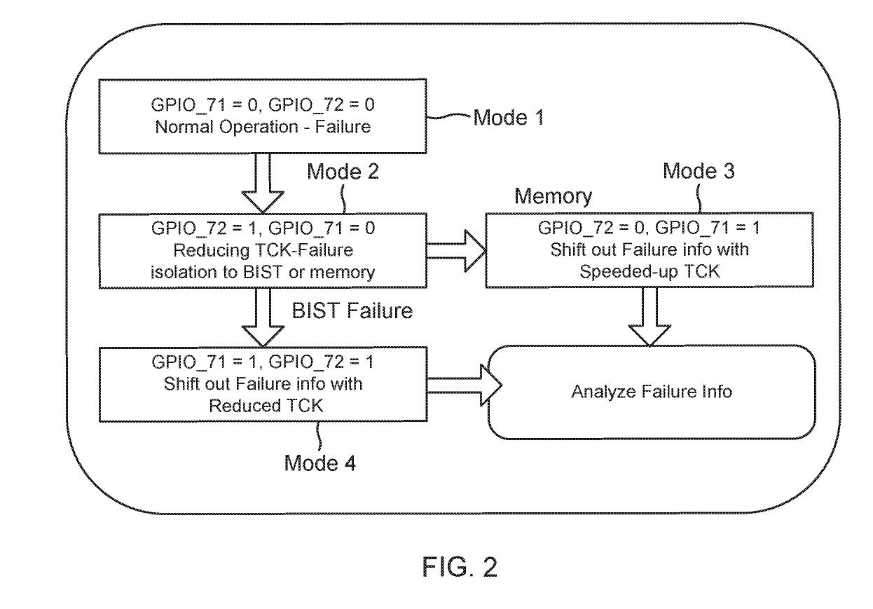

An example BIST process flow for the BIST circuit of FIG. 1 is shown in FIG. 2. The testing begins with the first mode of operation (Mode 1) in which both GPIO_71 and GPIO_72 equal zero. Such binary values are arbitrary and may be varied in alternative implementations. Moreover, other types of signals may be used to select for the various modes of operation. Regardless of the particular signal values, the first mode of operation uses the advanced clock rate (the system clock rate) to shift in the test vector and test the circuit that is the subject of the BIST operation (for example, memory 120). Should there be no failure, the BIST process flow would stop. Assuming that a failure is detected, the process flow continues with the second mode of operation (Mode 2) in which the test vector is shifted into memory 120 according to the reduced clock rate (the test clock rate). This shifting may occur such that one bit is shifted into memory 120 for each cycle of the system clock signal. The second mode of operation may be selected for by the GPIO_72 signal equaling 1 and the GPIO_71 signal equaling 0. A passing result would indicate a BIST failure such that the process flow continues with the fourth mode of operation (Mode 4) to shift out the test vector at the reduced clock rate. In the fourth mode of operation, both the GPIO_71 and the GPIO_72 signals equal a binary one. Conversely, if the second mode of operation detects a failure, the process flow continues with the third mode of operation (Mode 3) to shift out the test vector at the increased clock rate such as selected by GPIO_71 equaling 0 and GPIO_72 equaling 1.

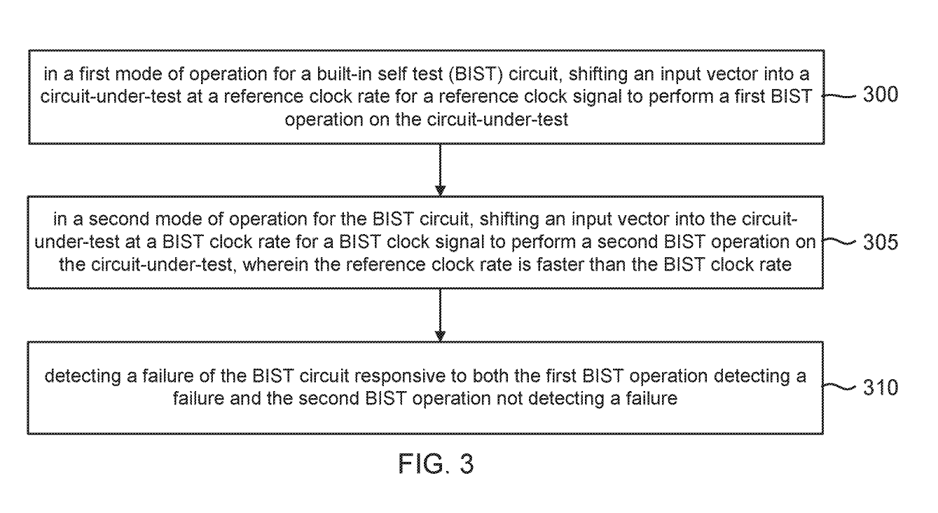

A method of operation for a BIST circuit configured to implement the first and second modes of operation will now be discussed with regard to the flowchart of FIG. 3. The method begins with an act 300 of, in a first mode of operation for a built-in self test (BIST) circuit, shifting an input vector into a circuit-under-test at a reference clock rate for a reference clock signal to perform a first BIST operation on the circuit-under-test. The shifting of a test vector into memory 120 at the reference clock rate is an example of act 300. The method further includes an act 305 of, in a second mode of operation for the BIST circuit, shifting an input vector into the circuit-under-test at a BIST clock rate for a BIST clock signal to perform a second BIST operation on the circuit-under-test, wherein the reference clock rate is faster than the BIST clock rate. Finally, the method includes an act 310 of detecting a failure of the BIST circuit responsive to both the first BIST operation detecting a failure and the second BIST operation not detecting a failure. The detection of the BIST circuit failure as discussed with regard to FIG. 2 is an example of act 310.

As those of some skill in this art will by now appreciate and depending on the particular application at hand, many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

I claim:

1. An integrated circuit, comprising:
a circuit-under-test;
a clock source configured to produce a circuit clock signal for clocking the circuit-under-test, wherein the circuit clock signal is synchronous with a reference clock signal for the integrated circuit;
a clock selection circuit configured to select between a test clock signal and the reference clock signal to provide a selected clock signal, wherein the reference clock signal has a faster frequency than the test clock signal; and
a built-in-self-test (BIST) controller configured to shift a test vector into the circuit-under-test responsive to the selected clock signal.

2. The integrated circuit of claim 1, further comprising:
a terminal for receiving an external signal, wherein the clock selection circuit is configured to select between the test clock signal and the reference clock signal responsive to a binary value for the external signal.

3. The integrated circuit of claim 2, wherein the external signal is a general-purpose-input-output (GPIO) signal.

4. The integrated circuit of claim 1, further comprising:
a test access port (TAP) configured to receive the selected clock signal from the clock selection circuit and to provide the selected clock signal to the BIST controller.

5. The integrated circuit of claim 1, wherein the TAP comprises a local TAP and a global TAP.

6. The integrated circuit of claim 1, wherein the BIST controller is further configured to respond to an assertion of an enable failure signal to shift out failure information for the circuit-under-test responsive to the selected clock signal.

7. The integrated circuit of claim 6, further comprising:
a terminal for receiving an external signal; and
a multiplexer configured to select between a binary zero signal and a binary one signal to form the enable failure signal responsive to the external signal.

8. The integrated circuit of claim 7, wherein the external signal is a GPIO signal.

9. The integrated circuit of claim 1, wherein the integrated circuit is a system-on-a-chip (SoC) and wherein the circuit-under-test is an embedded memory for the SoC.

10. The integrated circuit of claim 9, wherein the clock source comprises:
a phase-locked-loop (PLL) for producing a PLL output clock signal responsive to the reference clock signal; and
a clock divider for dividing the PLL output clock signal into a memory clock signal for clocking the embedded memory, wherein the memory clock signal is also a BIST clock signal for clocking the BIST controller.

11. The integrated circuit of claim 1, wherein the clock selection circuit comprises a multiplexer and a logic for controlling a selection by the multiplexer.

12. A method, comprising:
in a first mode of operation for a built-in self test (BIST) circuit, shifting an input vector into a circuit-under-test at a reference clock rate for a reference clock signal to perform a first BIST operation on the circuit-under-test;
in a second mode of operation for the BIST circuit, shifting an input vector into the circuit-under-test at a BIST clock rate for a BIST clock signal to perform a second BIST operation on the circuit-under-test, wherein the reference clock rate is faster than the BIST clock rate; and
detecting a failure of the BIST circuit responsive to both the first BIST operation detecting a failure and the second BIST operation not detecting a failure.

13. The method of claim 12, further comprising:
in a third mode of operation for the BIST circuit, shifting out an output vector resulting from the first BIST operation responsive to the reference clock rate; and
in a fourth mode of operation for the BIST circuit, shifting out an output vector resulting from the second BIST operation responsive to the BIST clock rate.

14. The method of claim 12, further comprising:
generating a memory clock that is synchronous with the reference clock signal; and
clocking an embedded memory with the reference clock signal, wherein the circuit-under-test comprises the embedded memory.

15. The method of claim 12, wherein the reference clock rate is four times the BIST clock rate.

16. The method of claim 13, further comprising:
selecting for the first mode of operation for the BIST circuit responsive to an de-assertion of both a first general-purpose-input-output (GPIO) signal and of a second GPIO signal; and
selecting for the third mode of operation for the BIST circuit responsive to the de-assertion of the first GPIO signal and an assertion of the second GPIO signal.

17. The method of claim 16, further comprising:
selecting for the second mode of operation for the BIST circuit responsive to an assertion of the first GPIO signal and a de-assertion of the second GPIO signal; and
selecting for the fourth mode of operation for the BIST circuit responsive to an assertion of both the first GPIO signal and of the second GPIO signal.

18. An integrated circuit, comprising:
a circuit-under-test;
a clock source configured to produce a circuit clock signal for clocking the circuit-under-test, wherein the circuit clock signal is synchronous with a reference clock signal for the integrated circuit;
a built-in-self-test (BIST) controller; and
means for driving the BIST controller into a first mode of operation in which the BIST controller shifts a test vector into the circuit-under-test responsive to the reference clock signal and for driving the BIST controller into a second mode of operation in which the BIST controller shifts a test vector into the circuit-under-test responsive to a BIST clock signal, wherein a frequency for the reference clock signal is faster than a frequency for the BIST clock signal.

19. The integrated circuit of claim 18, wherein the means is further configured to drive the BIST controller into a third mode of operation in which failure information from the first mode of operation is shifted out of the BIST controller responsive to the reference clock signal and to drive the BIST controller into a fourth mode of operation in which failure information from the second mode of operation is shifted out of the BIST controller responsive to the BIST clock signal.

20. The integrated circuit of claim 18, wherein the reference clock signal is a crystal oscillator signal.
